(19) United States
(12) Patent Application Publication
(10) Pub. No.: US 2016/0244359 A1
(43) Pub. Date: Aug. 25, 2016

(54) MAGNESIUM GLASS

(71) Applicant: Ashok Chaudhari, Briarcliff Manor, NY (US)

(72) Inventor: Ashok Chaudhari, Briarcliff Manor, NY (US)

(73) Assignee: Solar-Tectic LLC, Briarcliff Manor, NY (US)

(21) Appl. No.: 15/147,276

(22) Filed: May 5, 2016

Related U.S. Application Data
(60) Provisional application No. 62/157,532, filed on May 6, 2015.

(51) Int. Cl. C03C 17/245; C23C 14/30; C23C 14/08; C03C 3/06

(52) U.S. Cl. CPC C03C 17/245; C03C 3/06; C23C 14/30; C23C 14/082; C03C 2201/02; C03C 2217/228; C03C 2217/78

(57) ABSTRACT

A method of making magnesium glass including depositing a film of transparent crystalline MgO on glass at a temperature between 550° C. and 1000° C. by non-sintering, electron-beam evaporation. Such magnesium glass having an ideal grain size for a high Vickers hardness value.

This application claims priority to U.S. Provisional Patent Application Ser. No. 62/157,532 filed May 6, 2015, entitled “Magnesium Glass” and is hereby incorporated by reference in its entirety.

The present invention relates to cover glass for all kinds of display and window applications, used for example in smartphones, watches, and the automotive industry.

### BACKGROUND OF THE INVENTION

Today there is a growing need for glass that is hard and strong that can be used in electronic devices such as smartphones and smartwatches, which are increasingly a part of daily life. An ideal material and manufacturing process would involve deposition of a hard coating on inexpensive glass or fused silica (quartz) with attributes such as transparency and hardness, and that is also affordable. Towards this end, we have discovered that when crystalline MgO is deposited with high texture, for example [111] orientation, as a film with small grains, the hardness measurements can be surprisingly up to ˜1400 Vickers easily satisfying a hardness requirement for anti-scratch surfaces. While it is known that MgO thin-films are transparent, they have not been used as coatings for anti-scratch purposes as of the date of this disclosure. It is also noteworthy for comparison that single crystalline MgO wafers, which typically represent the highest hardness potential of a material, have a hardness of around 800 Vickers. (see FIG. 1). We believe the increase in hardness of the MgO films we disclose here is due to the Hall-Petch Relationship, a well-known phenomenon stating that a decrease in grain size of certain materials, such as ceramics, leads to an increase in hardness. Recently, this phenomenon has been described by Wollmerhauser et al (see “An extended hardness limit in bulk ceramics nanoceramics” by Wollmerhauser et al, Acta Materialia 69 (2014) 9-16) and Ehre et al (see “Abnormal Hall-Petch behavior in nanocrystalline MgO ceramic” by Ehre et al, J Mater Sci (2008) 43:6139-6143) in connection with ceramics such as MgO. However, there is a major difference between what they report and what is disclosed herein. Wollmerhauser et al. explores the Hall-Petch relationship in oxide ceramics fabricated via high-pressure, low-temperature sintering of treated non-agglomerated nanoscale (21.1-33.6 nm) and submicron (200 nm) MgAl2O4 spinel powders, and Ehre et al. uses hot-pressing. In contrast, the method disclosed here uses a non-sintering, electron beam evaporation approach for the first time, thus providing an entirely new and simple approach to manufacturing hard, transparent, coatings. It should also be noted that while other anti-scratch cover glass techniques have been disclosed (see for example US 2015/0267289 A1 “Method of Making Ceramics Glass” Vispute et al) the method disclosed here involves only one material and one layer, thus greatly simplifying fabrication and reducing costs. Finally, it should be noted that Gorilla Glass, commonly used today in the trade for device covers, has a Vickers hardness measurement of 649. Thus the Magnesium Glass we report here is at least ˜20% harder and cheaper than Gorilla glass which dominates the market right now.

### SUMMARY OF THE INVENTION

It is an object of the present invention to provide an improved method of making cover glass.

It is yet another object of this invention to provide a method of making hard cover glass that is less expensive than that currently used in the art.

It is yet another object of this invention to provide a method of making a hard cover glass that is scalable and can be applied over a large area.

Magnesium glass, consisting of a hard layer of Magnesium oxide on fused silica or quartz or any other suitable transparent amorphous substrate, is made for anti-scratch cover glass.

### BRIEF DESCRIPTION OF THE DRAWINGS

FIG. 1 shows the results of a hardiness testing on MgO (111) single crystal;

FIG. 2 shows the results of 3 μm of MgO deposited on fused silica at 900° C., having a Vickers hardness measurement over 1600;

FIG. 3 shows an XRD of 3 μm MgO/quartz at 800° C. having near perfect alignment along the (111) plane (and associated (222) plane and grain size estimation of 58 nm based on the Scherrer's equation;

FIG. 4 shows the results of Example 1 and also FIG. 3, having Vickers hardness values over 1400 achieved; and

FIG. 5 shows a XRD of 2.2 Al₂O₃ on MgO+Al on quartz and annealed at 1000° C. for 36 hours, the grain size of the MgO increasing to 1208 Å or 110 nm.

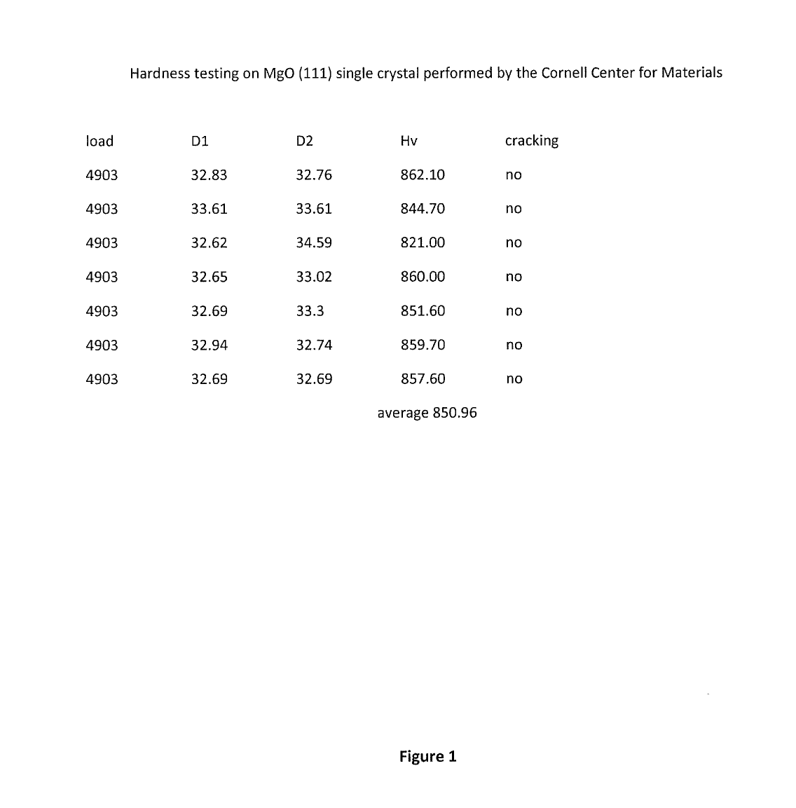

### DETAILED DESCRIPTION OF THE INVENTION

Using a common electron beam (e-beam) evaporation process known in the trade, or any other deposition method commonly used in the field of materials science, such as CVD or sputtering, MgO is deposited on a soda-lime, borosilicate, alumino-silicate, fused silica (quartz) or other glass substrate at a temperature that enables crystallization. The crystalline MgO film in this particular embodiment has a preferred [111] orientation, but other orientations are possible. The film thickness can vary, for example anywhere between 1-7 microns, and the deposition temperature can also vary, for example anywhere from 550° C. to 1000° C. The grain size of the MgO film is important to achieving the increased hardness, and there is an ideal size, approximately 130 nm. Larger grain sizes may be beneficial ranging up to 250 nm. Generally speaking, following the Hall-Petch relationship, a decrease in grain size leads to increased hardness. The technique disclosed here makes use of a highly textured MgO film with very small grain sizes. This leads to advantages over the current cover glass art, such as increased hardness, which would not be possible using current deposition techniques. The smoothness of the MgO films on glass can be controlled by adjusting the MgO film thickness. Thinner films lead to smoother films having an ideal roughness value less than 10 nm. Lower deposition temperatures also increase film smoothness. The films disclosed in the examples herein were fabricated between 800° C. and 1000° C., but lower temperatures may be desirable followed by annealing, as shown in Example 4, for increased hardness and grain size.

Ehre et al (see “Abnormal Hall-Petch behavior in nanocrystalline MgO ceramic” by Ehre et al, J Mater Sci (2008) 43:6139-6143) reported crystalline MgO with hardness of 13 GPa from 130 nm grains by using hot-pressing. In the method disclosed here hardness of up to 14 GPa was achieved and importantly it was done by simple electron beam deposition of thin-films of 3 μm MgO on fused silica (quartz) thus saving considerable material and cost. In example 4 (below) grain size average of the MgO film was 120 nm, approaching the 130 nm grain size reported by Ehre et al which leads to high hardness values (13 GPa). It is expected that with some minor adjustments of parameters, the same grain size can be achieved using the technique disclosed here.

### EXAMPLE 1

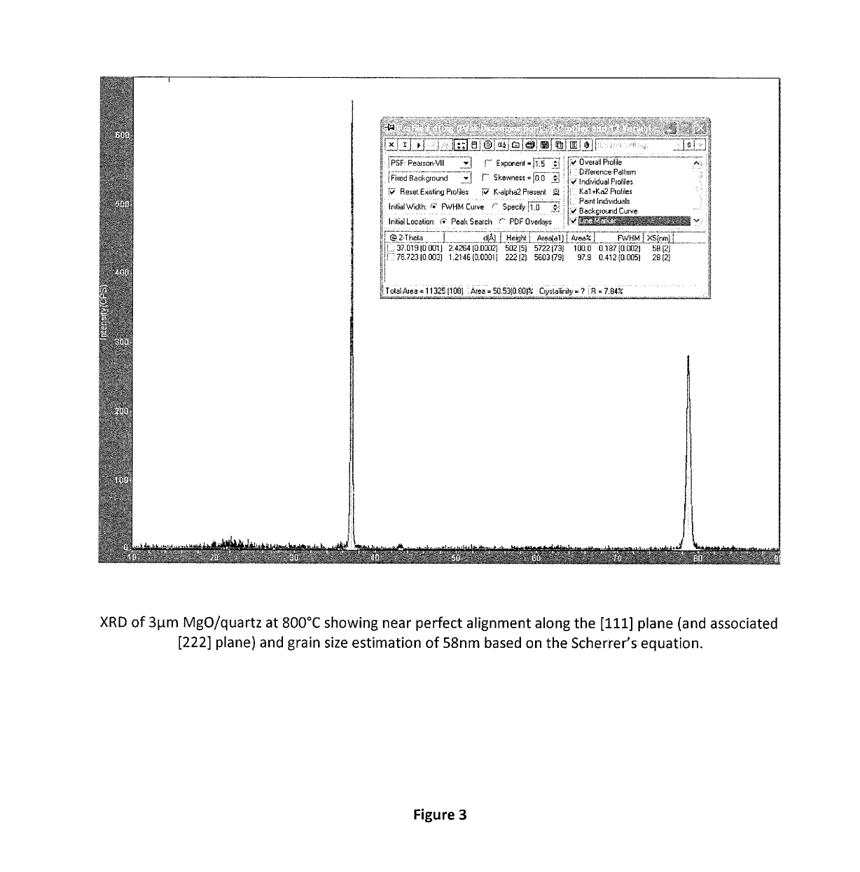

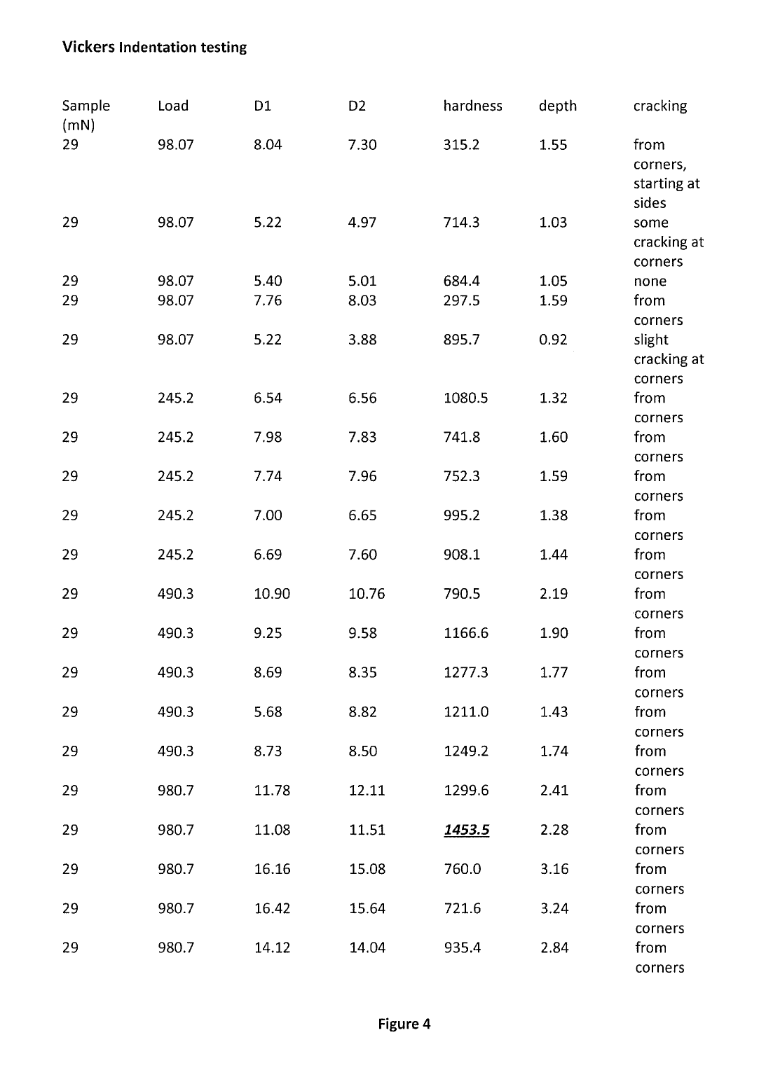

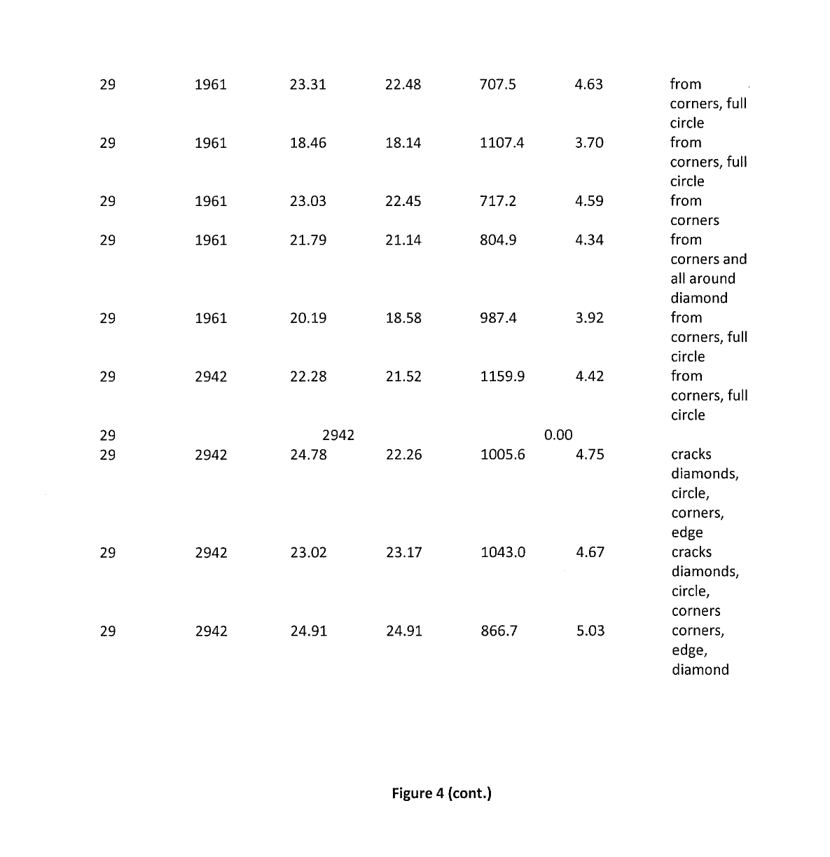

Using electron beam evaporation, 3 μm of MgO was deposited on a fused silica (quartz) substrate at 800° C. The evaporator consists of a stainless steel high vacuum chamber capable of reaching 10E-7 Torr with the help of a cryopump. Initial rough vacuum up to 10E-3 Torr is achieved with a mechanical dry pump. Prior to vacuuming the chamber, batches of initial glass substrates are loaded on a substrate heater that is capable of controlling temperature of the substrates while growing the MgO buffer layer in reactive deposition mode. A typical buffer layer of MgO layer is grown from stoichiometric MgO source material. The presence of background pressure of O₂ (10E-4 Torr using O₂ flow need valve) helps high quality stoichiometric MgO depositions. The sample produced here is fully transparent. Grain size was determined to be 58 nm based on the Scherrer's equation (see FIG. 3). Hardness values up to 1400 Vickers were achieved (see FIG. 4). Additionally, a silica sand vibration test for 10000 cycle was done to see the performance of wear resistance. After 10000 cycle vibration, the surface was good but a little bit of haze occurred. The optical surface reflection was greater than glass and needs to be improved.

### EXAMPLE 2

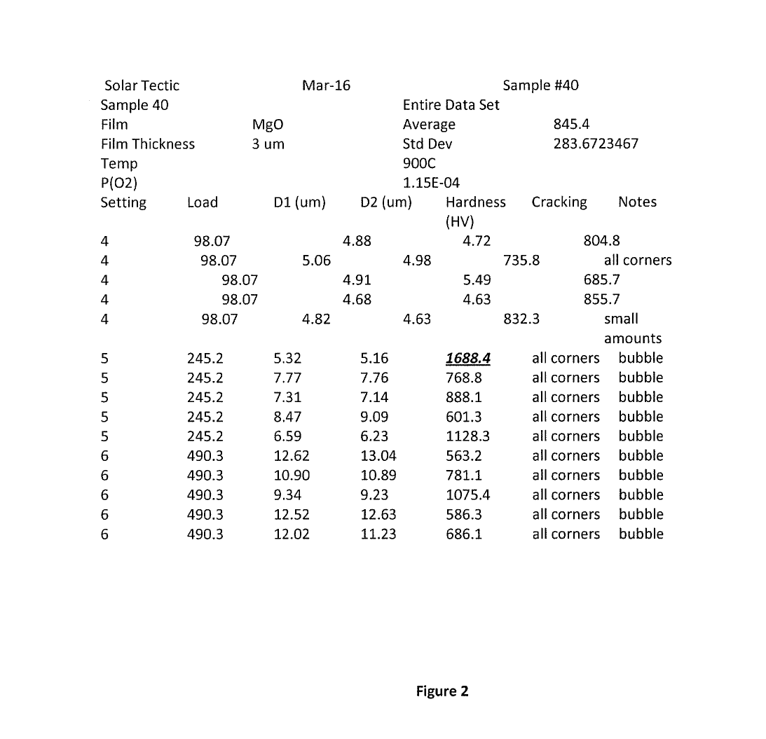

Using electron beam evaporation, 3 μm of MgO is deposited on fused silica (quartz) at 900° C. The evaporator consists of a stainless steel high vacuum chamber capable of reaching 10E-7 Torr with the help of a cryopump. Initial rough vacuum up to 10E-3 Torr is achieved with a mechanical dry pump. Prior to vacuuming the chamber, batches of initial glass substrates are loaded on a substrate heater that is capable of controlling temperature of the substrates while growing the MgO buffer layer in reactive deposition mode. A typical buffer layer of MgO layer is grown from stoichiometric MgO source material. The presence of background pressure of O₂ (10E-4 Torr using O₂ flow need valve) helps high quality stoichiometric MgO depositions. The sample produced here is fully transparent. Vickers hardness measurements up to 1600 were obtained (see FIG. 2).

### EXAMPLE 3

Using electron beam evaporation, 3 μm of MgO is deposited on fused silica (quartz) at 1000° C. The evaporator consists of a stainless steel high vacuum chamber capable of reaching 10E-7 Torr with the help of a cryopump. Initial rough vacuum up to 10E-3 Torr is achieved with a mechanical dry pump. Prior to vacuuming the chamber, batches of initial glass substrates are loaded on a substrate heater that is capable of controlling temperature of the substrates while growing the MgO buffer layer in reactive deposition mode. A typical buffer layer of MgO layer is grown from stoichiometric MgO source material. The presence of background pressure of O₂ (10E-4 Torr using O₂ flow need valve) helps high quality stoichiometric MgO depositions. The sample produced here is fully transparent.

### EXAMPLE 4

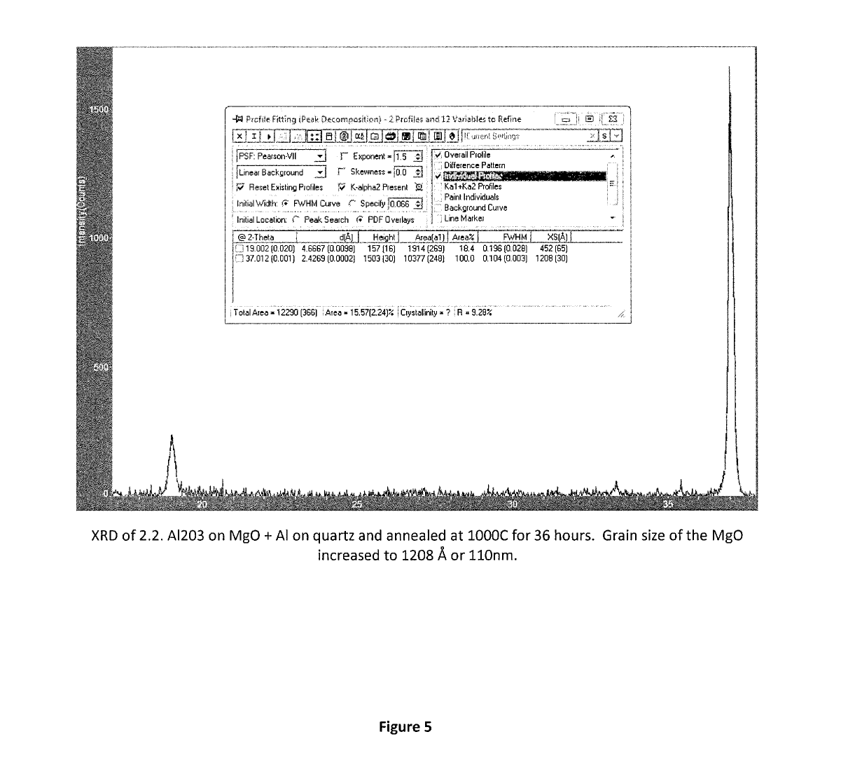

Using electron beam evaporation, 3 μm of MgO is deposited on fused silica (quartz) at 600° C. followed by 2.2 um Al₂O₃+20 nm Al and annealing at 1000° C. for 36 hours. Grain size of Al₂O₃ was 42 nm and MgO 110 nm. (See FIG. 5) The evaporator consists of a stainless steel high vacuum chamber capable of reaching 10E-7 Torr with the help of a cryopump. Initial rough vacuum up to 10E-3 Torr is achieved with a mechanical dry pump. Prior to vacuuming the chamber, batches of initial glass substrates are loaded on a substrate heater that is capable of controlling temperature of the substrates while growing the MgO buffer layer in reactive deposition mode. A typical buffer layer of MgO layer is grown from stoichiometric MgO source material. The presence of background pressure of O₂ (10E-4 Torr using O₂ flow need valve) helps high quality stoichiometric MgO depositions. Grain size of Al₂O₃ was 42 nm and MgO 120 nm. (See FIG. 5) The grain size of MgO increased to 120 nm (from 58 nm).

While the present invention has been described in conjunction with specific embodiments, those of normal skill in the art will appreciate the modifications and variations can be made without departing from the scope and spirit of the present invention Such modifications an variations are envisioned to be within the scope of the appended claims.

What is claimed is:

1. A method of making magnesium glass comprising steps of:
depositing a film of crystalline MgO on glass at a temperature between 550° C. and 1000° C.

2. The method of claim 1, where the MgO is highly textured.

3. The method of claim 1, where the MgO film has grains ranging between 58 nm and 250 nm.

4. The method of claim 1, where said magnesium glass is fully transparent.

5. The method of claim 1, where said magnesium glass has a hardness value greater than 800 Vickers.

6. The method of claim 17, where said hardness value of said magnesium glass is greater than 1200 Vickers.

7. The method of claim 1, where said hardness value of said magnesium glass is greater than 1400 Vickers.

8. The method of claim 1, where said magnesium glass has a roughness value of less than 10 nm.

9. The method of claim 1, where said magnesium glass has a roughness value of less than 5 nm.

10. The method of claim 1, where said magnesium glass is annealed from between 1 and 36 hours.

11. The method of claim 1, where the Hall-Petch effect causes hardness.

12. The method of claim 1, where said MgO film is deposited by electron beam evaporation.

13. The method of claim 1, where said MgO film passes a silica sand vibration test for 10000 cycle.

14. The method of claim 1, where said MgO film is deposited by a non-sintering process.

15. The method of claim 1, where said MgO film is smooth.

16. The method of making magnesium glass comprising:
loading batches of substrate onto a substrate heater;
heating the substrate with the substrate heater to a controlled temperature;
depositing MgO film on the substrate; and
increasing the MgO film grain size.

17. The method of claim 1, further comprising increasing a hardness value of the magnesium glass.
